(19) United States
(12) Patent Application Publication
(10) Pub. No.: US 2020/0205295 A1
(43) Pub. Date: Jun. 25, 2020

(54) System, Apparatus and Method for Utilizing Surface Mount Technology on Metal Substrates

(71) Applicant: Jabil Inc., St. Petersburg, FL (US)

(72) Inventors: Weiping (aka Jonathan) Wu, Penang (MY); Mohd Yusuf Tura Ali, Penang (MY); Zambri Samsudin, Penang (MY)

(73) Assignee: Jabil Inc., St. Petersburg, FL (US)

(21) Appl. No.: 16/622,381

(22) PCT Filed: Jun. 15, 2017
(86) PCT No.: PCT/MY2017/050027

§ 371 Date: Dec. 13, 2019

(51) Int. Cl. H05K 3/18; H05K 1/18; H05K 1/11; H05K 1/05; H05K 3/28; H05K 3/00; C23C 18/16; C23C 18/18; C25D 7/12

(52) U.S. Cl. CPC H05K 3/182; H05K 1/181; H05K 1/111; H05K 1/05; H05K 3/28; H05K 2203/0502; C23C 18/1608; C23C 18/1653; C23C 18/1827; C25D 7/12; H05K 2203/107; H05K 3/0026

(57) ABSTRACT

A method for forming a circuit pattern on an integrated substrate structure includes providing an insulating surface which includes a pattern forming portion. An activation ink is deposited only on the pattern forming portion to form a non-conductive isolation layer. A first metal layer is formed on the non-conductive isolation layer by electroless plating. A patterned portion of the first metal layer is isolated from a remaining portion of the first metal layer to form the circuit pattern. A non-conductive masking layer is applied on the first metal layer. A second metal layer is formed on the non-conductive masking layer. A surface mount land pattern and pad configuration is determined. A solder mask layer is applied to the patterned portion. A protective layer is applied to protect pad areas not covered by the solder mask layer. An electrical component may then be mounted to the pad(s).

### FIELD

The present disclosure generally relates to formation of electronic circuitry and electronic devices and in particular, to methods for using surface mounts technology on metal substrates.

### BACKGROUND

As electronic and processing devices evolve, there is an increased need to miniaturize and integrate electronic components. Currently, many conventional device components are assembled using soldering techniques. For such techniques, components are generally soldered onto a rigid or flex printed circuit substrate to form a printed circuit board assembly (PCBA), with typical lead free process temperature ranges of 220 to 250° C. or more, or typical tin lead process temperature ranges of 180 to 220° C. Once the PCBA is formed, it is then attached or integrated into a device, a device portion or a product chassis, such as to form a final product.

With the advent of 3-dimensional (3D) printing and structural electronics, devices or products of various and/or unique shapes, sizes and/or dimensions, often in relative miniature scale, are being fabricated, and these unique devices and products often require dedicated cavities, spaces and/or areas to accommodate the aforementioned PCBA circuitry. Among various drawbacks, such as the at least partially inflexible nature of most conventional PCBA circuitry arrangements, the insertion of electronics to these devices may carry a significant cost in space requirements that is highly undesirable because of the referenced unique and often miniature nature of these products and devices.

### SUMMARY

Described herein is a system and method for placing surface mount technology components directly onto a metal substrate with circuitry pattern. A method for forming a circuit pattern on a metal substrate structure includes providing the metal substrate structure with an insulating surface which includes a pattern forming portion. An activation ink is deposited (i.e. printed and other similar techniques) only on the pattern forming portion of the insulating surface to form a non-conductive isolation layer on the pattern forming portion of the insulating surface. A first metal layer is formed on the non-conductive isolation layer by electroless plating. A patterned portion of the first metal layer is isolated from a remaining portion of the first metal layer to form the circuit pattern. A non-conductive masking layer is applied on the first metal layer. A second metal layer is formed on the non-conductive masking layer. A surface mount land pattern and pad configuration is determined. A solder mask layer is applied to the patterned portion to protect the circuit pattern. A protective layer is applied to protect the pad areas not covered by the solder mask layer.

### BRIEF DESCRIPTION OF THE DRAWINGS

Other features and advantages of the disclosure will become apparent in the following detailed description of the exemplary embodiment with reference to the accompanying drawings, of which:

FIG. 1 is a flow chart illustrating a method for placing surface mount technology components on a metal substrate with circuitry pattern in accordance with certain implementations;

FIG. 2 is an example metal substrate in accordance with certain implementations;

FIG. 3 is a flow chart for preparing an insulated metal substrate in accordance with certain implementations;

FIG. 4 is a schematic view, illustrating forming an activation or circuit layer on a portion of an insulating surface on an insulated metal substrate in accordance with certain implementations;

FIG. 5 is a pad structure for placement of surface mount technology components in accordance with certain implementations;

FIGS. 6A and 6B are schematic views illustrating surface mount technology components mounted on a metal substrate with circuitry pattern in accordance with certain implementations;

FIG. 7 is an example photograph of surface mount technology component leads soldered to pad structure on a metal substrate with circuitry pattern in accordance with certain implementations;

FIG. 8 is an example photograph of surface mount technology component leads soldered to pad structure on a metal substrate with circuitry pattern in accordance with certain implementations;

FIG. 9 is a heat diagram of conventional placement of surface mount technology component on printed circuit board then mounted on a metal substrate; and

FIG. 10 is a heat diagram of surface mount technology components on a metal substrate with circuitry pattern in accordance with certain implementations.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, a discussion of such elements and operations may not be provided herein. However, the present disclosure is deemed to nevertheless include all such elements, variations, and modifications to the described aspects that would be known to those of ordinary skill in the art.

Exemplary embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure.

Nevertheless, it will be apparent to those skilled in the art that specific disclosed details need not be employed, and that exemplary embodiments may be embodied in different forms. As such, the exemplary embodiments should not be construed to limit the scope of the disclosure. In some exemplary embodiments, well-known processes, well-known device structures, and well-known technologies may not be described in detail.

The terminology used herein is for the purpose of describing particular exemplary embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the exemplary embodiments.

Described herein is a system and method for placing surface mount technology (SMT) components directly onto a metal substrate with circuitry pattern or similar substrate. For purposes of illustration only, an integrated substrate can include a metal baseplate covered by a thin layer of dielectric and a layer of copper.

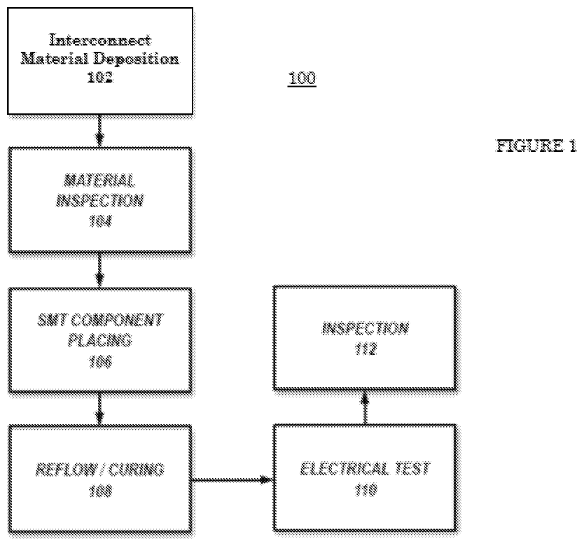

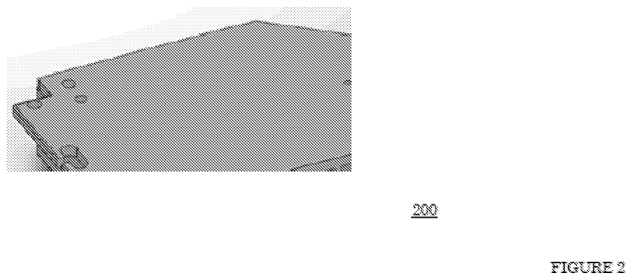

FIG. 1 is an assembly process flow or flow chart 100 illustrating a method for placing surface mount technology components on a metal substrate with circuitry pattern. An integrated substrate structure is provided that can be processed for placement of SMT components (block 102). The integrated substrate structure can be a 2-dimensional, 2.5-dimensional or 3-dimensional, for electronic devices and systems. The integrated substrate structure can be formed using a variety of techniques known to one of ordinary skill in the art, e.g. one of Insulated Metal Substrate Technology (IMST®) developed by ON Semiconductor. An example metal substrate heat sink 200 is shown in FIG. 2.

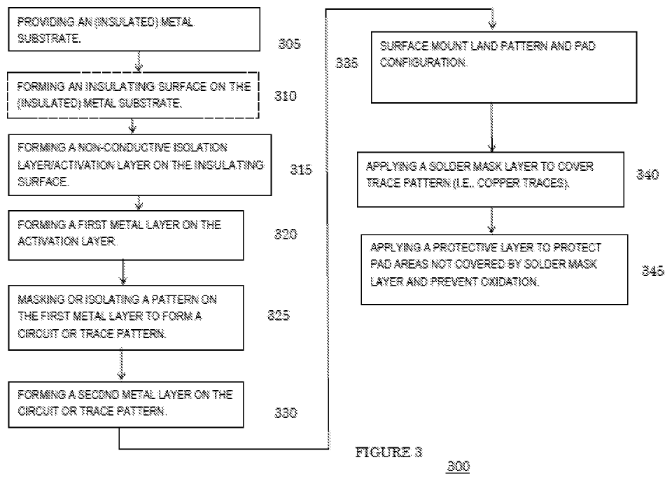

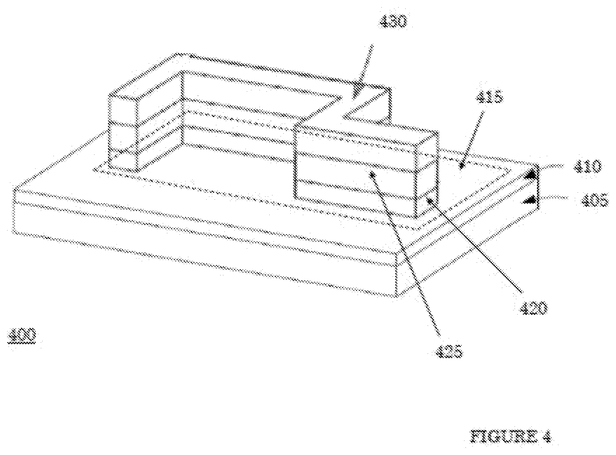

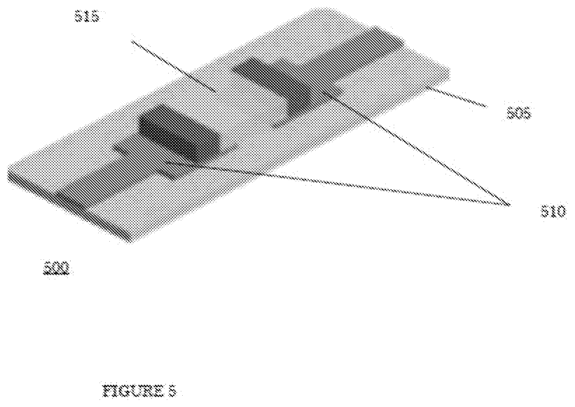

The integrated substrate structure is processed in accordance with FIG. 3 using printed laser selective plating (PLSP), which is described in U.S. Patent Application Publication No. 2016/0186327, filed Dec. 23, 2015, and which is incorporated by reference as if fully set forth. In particular, FIG. 3 is an illustrative method or flow chart 300 for forming a circuit pattern on a metal structure. FIG. 3 is described in combination with FIGS. 2, 4 and 5. FIG. 4 shows an illustrative processed integrated substrate structure 400 and FIG. 5 shows an illustrative pad structure 500.

As described above, an integrated substrate structure (also referred to as substrate herein) is provided (block 305). For example, the integrated substrate structure can be a part of a product using a heat sink 200, such as a cell phone, a touch panel, a watch, glasses, etc. Referring now also to FIG. 4, the integrated substrate structure is schematically shown as layer 405, which can be a metal, dielectric and copper structure. In the event an insulating layer 410 is needed, this can be formed by spray coating, screen printing, transferring, or the like, and may be made of insulating paints or inks (block 310). Insulating surface 410 is not limited to being planar, i.e., the insulating surface 410 can follow the structure of the integrated substrate structure.

An activation ink is printed on a portion 415 (pattern forming region) of insulating surface 410 so as to form a non-conductive isolation layer or activation layer 420 on portion 415 of insulating surface 410 (block 315). Note that non-conductive isolation layer 420 is initially the same dimensions as portion 415 prior to the processing described herein. In certain embodiments, non-conductive isolation layer 420 may include a catalyst metal element which is selected from the group consisting of palladium, rhodium, platinum, silver, and combinations thereof. In certain embodiments, non-conductive isolation layer 420 may be made of a metal oxide compound that is electrically non-conductive. Activation ink printing can be conducted by digital printing, screen printing, pad printing, transfer printing, coating, spraying, or powder coating techniques. These techniques are illustrative and non-limiting. Activation ink can include but is not limited to N-methyl-2-pyrrolidone (NMP) which can slightly etch insulating surface 410 when the same is being applied onto insulating surface 410. As such, a conventional step of roughening insulating surface 410 to increase the bonding strength between activation layer 420 and insulating surface 410 may be omitted.

A first metal layer 425 is formed on activation layer 420 by electroless plating (block 320). In certain embodiments, this may be conducted by placing the substrate with the non-conductive isolation layer 420 into an electroless plating solution for a predetermined period of time, so as to perform the electroless plating reaction. In certain embodiments, first metal layer 425 may have a thickness ranging from 0.1 μm to 0.251 μm. In certain embodiments, first metal layer 425 may be made of nickel, but is not limited thereto. For example, first metal layer 425 may be made of copper in certain embodiments.

A patterned portion 422, (also known as circuit or trace pattern), is isolated from a remaining portion 423 (block 325), where portion 415 is equal to patterned portion 422 plus remaining portion 423. In certain embodiments, this may include removing part of first metal layer 425 so as to form a gap (not shown) along an outer periphery of patterned portion 422 to isolate patterned portion 422 of first metal layer 425. The removal of the part of first metal layer 425 may be conducted by laser ablation. In certain embodiments, patterned portion 422 of first metal layer 425 may be surrounded by remaining portion 423 of first metal layer 425. In certain embodiments, a patterned portion of non-conductive isolation layer 420 may be isolated, e.g., by laser ablation, where patterned portion of non-conductive isolation layer 420 corresponds in position to patterned portion 422 of first metal layer 425 as described herein. In certain embodiments, where activation layer 420 is electrically non-conductive, the gap does not need to extend into non-conductive isolation layer 420 considering the subsequent electroplating process.

A second metal layer 430 is formed on patterned portion 422 of first metal layer 425 by electroplating (block 330). In certain embodiments, second metal layer 430 may be made of copper, i.e., using copper-containing electroplating solution with copper electrodes during the electroplating process. In certain embodiments, second metal layer 430 may have a thickness ranging from 0.2 μm to 0.5 μm. Since patterned portion 422 of first metal layer 425 is isolated from remaining portion 423, second metal layer 430 can only be formed on patterned portion 422 of first metal layer 425 during the electroplating process.

In certain embodiments, the method may further include a step of removing remaining portion 423 of first metal layer 425. Such a step may be performed by wet-etching techniques or laser ablation and is not limited thereto according to the present disclosure.

In certain embodiments, the method may further include a step of removing part of non-conductive isolation layer 420 which is located outside patterned portion 422. Such a step may be performed by applying a stripping solution onto the substrate, e.g., by spraying the stripping solution onto the substrate or by dipping the substrate into the stripping solution. As such, non-conductive isolation layer 420 is softened due to the stripping solution, and the bonding between non-conductive isolation layer 420 and insulating surface 410 of the substrate is diminished, thereby allowing the same to be removed from insulating surface 410 of the substrate. In certain embodiments, the step of removing non-conductive isolation layer 420 may be conducted by laser ablation.

Surface mount land pattern(s) for soldering are determined, followed by a pad configuration for the determined pattern (block 335). In order to provide desired connectivity and to increase reliability of the attachment of the surface mount components, specific pad layouts on the integrated substrate structure may be designed to increase and/or maximize the amount of integrated substrate structure and pad surface area contact. Such a configuration should promote stronger bonding through mechanical and chemical bonds, and also may help to absorb at least some forces created by potential mismatches of CTE between the traces, substrate, interconnect material and the component terminals. An example pad configuration 500 is shown in FIG. 5. In particular, integrated substrate structure 505 has pads 510 and component 515 mounted on pads 510. It should be understood by those skilled in the art that other pad configurations/geometries are contemplated in the present disclosure to allow soldering application to contact pads and the integrated substrate structure.

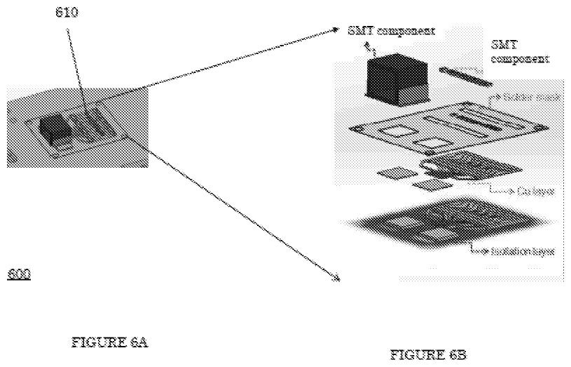

A solder mask layer may be applied to cover copper traces (e.g. patterned portion 422) to protect against corrosion, electrical short, avoid oxidation and environmental influences (block 340). If a solder mask is not applied, then the pad configuration design may be reconsidered. For bonding pads, test points and fiducial marks may or may not be required. Moreover, a silkscreen may be applied as a reference designator and pin marker for each SMT component designed for the integrated substrate structure. An example solder mask is shown in FIG. 6B.

A protective layer is applied to protect the pad areas not covered by solder mask layer and prevent oxidation (block 345). For example, a surface finish/plating layer may be applied which can be a resin layered with a plurality of metals that may include copper (Cu), nickel (Ni) and/or gold (Au), among other materials. Organic Solderability Preservative (OSP) may be used for high/regular temperature integrated substrate structure configurations. Preferably, smooth, glossy plating should be used instead of matte surface finishes, as rough plating surfaces may form inconsistent intermetallic compound thickness which may affect bonding reliability performance.

Referring back to FIG. 1, material inspection and measurement is performed, either manually, or through the use of machine-vision technologies (block 104). Once inspection is successfully completed, SMT components are placed on the pads of the integrated substrate structure (block 106). In an illustrative embodiment, such as for a 2D structure, conventional SMT machinery may employ typical SMT pick and place processes. For a 2.5D or 3D structure, special 3D capable placement machinery may be employed. In an illustrative embodiment, solder or similar bonding material is used to attach SMT components onto the integrated substrate structure. In particular, solder paste material and online reflow technology may be used for the component-substrate bonding process.

Once SMT component placement is determined, reflow and/or curing processes (if necessary) are performed (in block 108), followed by electrical testing (block 110) and inspection (block 112). Inspection may occur manually or automatically, such as using machine-vision technologies.

As described above, FIG. 2 is an example of a bare metal structure in accordance with certain implementations. FIGS. 6A and 6B are examples of the integrated substrate structure after undergoing the method described with respect to FIGS. 1 and 3. FIG. 6A illustrates a populated integrated substrate structure 600 with surface mounted components 610. FIG. 6B shows an exploded view that shows an isolation layer 615 (see block 315), a copper layer 620 (see block 330), a solder mask 625 (see block 340), surface mount components such as LEDs 630 and a connector 635.

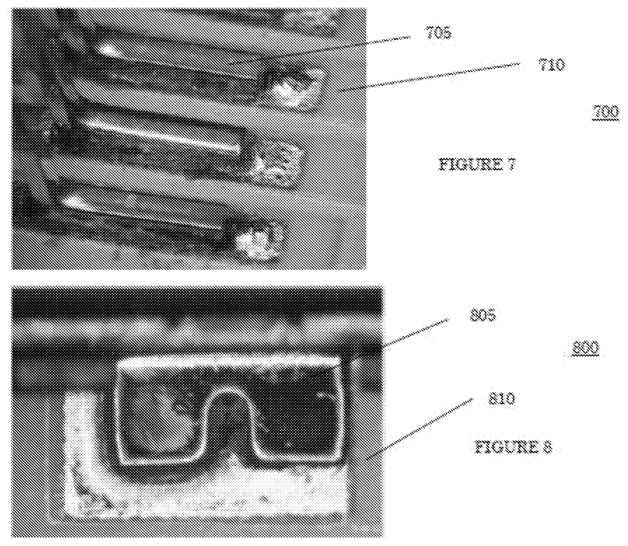

FIG. 7 is an example photograph of surface mount technology component leads 705 soldered to a pad structure 710 on an integrated substrate structure 700 in accordance with certain implementations. FIG. 8 is an example photograph of surface mount technology component leads 805 soldered to a pad structure 810 on an integrated substrate structure in accordance with certain implementations.

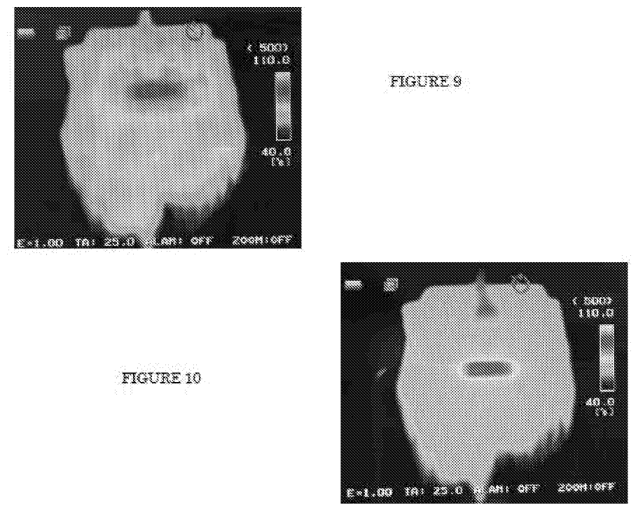

FIG. 9 is a heat diagram of conventional placement of surface mount technology component on a printed circuit board then mounted on a metal substrate. FIG. 10 is a heat diagram of surface mount technology components on an integrated substrate structure in accordance with certain implementations. As evident from the heat diagrams, there is greater and more even heat dissipation in the integrated substrate structure processed in accordance with the method described herein. Copper thickness and dimension need to be evaluated from an early stage to meet end product specific application requirement e.g. a thicker and larger copper dimension may be required for better thermal dissipation for high power product application.

Users may be able to assemble SMT components directly onto 3D structures to form a final product and enable integration of mechanical and electronic functions into a single device. Other advantages include, but are not limited to, enabling device miniaturization, integration, rationalization and feature advancement; providing shape flexibility and hybrid configurations that may shorten process chains; providing greater design flexibility to further improve portability and functionality; and reducing number of parts and substrates and total assembly time through integration. There are a wide variety of industry applications, including, but not limited to, automotive lighting applications, consumer applications (e.g., wireless chargers, power transmission touch sensors, camera module etc.), industrial applications (e.g., sensors, power controllers, battery containers, switching modules, OLED, etc.), and microelectronics, power electronics product application especially with high heat dissipation requirement i.e. LED lighting, power conversion, motor drives and semiconductor modules etc. For wire bonding on integrated substrate structure, soft surface finish/plating should be considered i.e. ENEPIG.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for forming a circuit pattern on a substrate, comprising the steps of:
providing a substrate having an insulating surface including a pattern forming portion;
printing only on the pattern forming portion of the insulating surface with an activation ink to form a non-conductive isolation layer on the pattern forming portion of the insulating surface;
forming a first metal layer on the non-conductive isolation layer by electroless plating; and
isolating a patterned portion of the first metal layer from a remaining portion of the first metal layer to form the circuit pattern.

2. The method of claim 1, wherein the step of printing with the activation ink is conducted by one of digital printing, screen printing, pad printing, transfer printing, coating, spraying, and powder coating.

3. The method of claim 1, wherein the step of isolating the patterned portion of the first metal layer is conducted by laser ablation.

4. The method of claim 3, wherein the step of isolating the patterned portion of the first metal layer includes removing part of the first metal layer along an outer periphery of the patterned portion to isolate the patterned portion of the first metal layer.

5. The method of claim 3, further comprising a step of isolating a patterned portion of the non-conductive isolation layer which is formed in the pattern forming region and which corresponds in position to the patterned portion of the first metal layer.

6. The method of claim 1, wherein the non-conductive isolation layer is electrically non-conductive.

7. The method of claim 1, wherein the substrate includes a metal base layer, and an insulating layer formed on the metal base layer to provide the insulating surface.

8. The method of claim 1, further comprising a step of forming a second metal layer on the patterned portion of the first metal layer by electroplating.

9. The method of claim 1, wherein the patterned portion of the first metal layer is surrounded by the remaining portion of the first metal layer.

10. The method of claim 1, wherein the activation ink includes N-methyl-2-pyrrolidone.

11. The method of claim 1, further comprising:
determining a surface mount land pattern and pad configuration;
applying a solder mask layer to cover the patterned portion; and
applying a protective layer to protect pad areas not covered by the solder mask layer.

12. The method of claim 1, further comprising:
soldering surface mount technology (STM) components to pads on the substrate.

13. An electronic circuit, comprising:
an integrated substrate structure comprising one or more electrically conductive traces comprising plating on a laser-etched, non-conductive isolated portion of the integrated substrate structure defining each electrically conductive trace;
one or more electrically conductive pads at one or more predetermined positions along the one or more electrically conductive traces; and
an electrical component surface mounted to the at least one electrically conductive pad with interconnect and bonding material.

14. The electronic circuit of claim 13, wherein the plating on a laser-etched, non-conductive isolated portion comprises:
a non-conductive isolation layer portion having an activation ink printed in a pattern forming region of an insulating surface of the integrated substrate structure;
a first metal layer formed on the non-conductive isolation layer; and
a second metal layer formed on the first metal layer.

15. The electronic circuit of claim 14, wherein the plating on a laser-etched, non-conductive isolated portion is formed by removing part of the first metal layer along an outer periphery of the one or more electrically conductive traces to isolate the one or more electrically conductive traces of the first metal layer.

16. The electronic circuit of claim 13, wherein the non-conductive isolated portion is electrically non-conductive.

17. The electronic circuit of claim 14, wherein the integrated substrate structure includes a metal base layer and an insulating layer formed on the metal base layer to provide an insulating surface.

18. The electronic circuit of claim 14, wherein the activation ink includes N-methyl-2-pyrrolidone.

19. The electronic circuit of claim 14, further comprising:
a solder mask layer to cover the one or more electrically conductive traces.

20. The electronic circuit of claim 19, further comprising:
a protective layer covering pad areas not covered by the solder mask layer.
